(19) United States
(12) Patent Application Publication
(10) Pub. No.: US 2026/0059920 A1
(43) Pub. Date: Feb. 26, 2026

(54) DISPLAY DEVICE

(71) Applicant: STAR ASIA VISION CORPORATION, Hsinchu City (TW)

(72) Inventors: Kuo-Shu Huang, Hsinchu City (TW); Kao-Nan Chen, Hsinchu City (TW); Yu-Hung Hsiao, Hsinchu City (TW); Yu-Chen Hsiao, Hsinchu City (TW)

(21) Appl. No.: 19/031,801

(22) Filed: Jan. 18, 2025

(30) Foreign Application Priority Data
Aug. 22, 2024 (TW) 113131565

(51) Int. Cl. H10H 29/855; H01L 25/075; H10H 29/24

(52) U.S. Cl. CPC H10H 29/855; H01L 25/0753; H10H 29/24

(57) ABSTRACT

A display device is provided. The display device comprises a substrate and a plurality of light-emitting units. Each of the light-emitting units includes a first light-emitting element, a first light shield, a second light-emitting element, a second light shield, a third light-emitting element, and a third light shield. The first, second, and third light-emitting elements are arranged on the substrate, respectively providing a first color light, a second color light, and a third color light, each with a light-emitting center. These color lights have different wavelengths, and the connections between their light-emitting centers form a triangle. The first light shield surrounds the first light-emitting element, the second light shield surrounds the second light-emitting element, and the third light shield surrounds the third light-emitting element. Each of the light shields has an opening, with a width of each of the openings being smaller than its length.

### CROSS-REFERENCES TO RELATED APPLICATIONS

This application claims the benefit of priority to Taiwanese Patent Application No. 113131565 filed on Aug. 22, 2024, which is hereby incorporated by reference in its entirety.

### BACKGROUND OF THE INVENTION

### FIELD OF THE INVENTION

The present invention relates to a display device, and in particular to a highly directional display device that provides image content within an appropriate viewing angle range.

### Descriptions of the Related Art

In modern society, advertising has become an indispensable part of our daily lives. With technological advancements, the number and scale of outdoor advertising billboards have been continuously increasing, especially in urban areas or along major roads, where these large billboards serve as important tools to capture consumers' attention.

However, with the increase in the number and size of outdoor advertising billboards, intense lighting has gradually started to interfere with people's daily lives. For residents living near mixed residential and commercial areas or along roads in rural areas, the strong light throughout the night affects their sleep and overall health. The natural ecosystem, including nocturnal animals and plant growth cycles, is also disrupted. Furthermore, excessive advertising lighting can easily distract drivers, reducing their reaction time and judgment, thereby compromising driving safety. Light pollution has become a problem that can no longer be ignored.

Therefore, without compromising the effectiveness of advertising, developing a display device that provides good advertising results while minimizing the impact of lighting on the surrounding environment has become a pressing issue in this industry.

### SUMMARY OF THE INVENTION

The objective of the present invention is to provide a display device with a narrower horizontal viewing angle, tailored to the deployment environment of the display device. Each light-emitting element of the pixels is individually adjusted by a light shield to control the emission angle, thereby addressing the issue of light pollution caused by the lighting of large advertising billboards affecting the surrounding environment.

To achieve the above objectives, the present invention discloses a display device comprising a substrate and a plurality of light-emitting units. Each of the light-emitting units includes a first light-emitting element, a first light shield, a second light-emitting element, a second light shield, a third light-emitting element, and a third light shield. The first light-emitting element is disposed on the substrate and is configured to provide a first color light with a first light-emitting center. The first light shield surrounds the first light-emitting element, and the first light shield has a first opening, wherein a width of the first opening is smaller than a length of the first opening. The second light-emitting element is disposed on the substrate and is configured to provide a second color light with a second light-emitting center. The second light shield surrounds the second light-emitting element, and the second light shield has a second opening, wherein a width of the second opening is smaller than a length of the second opening. The third light-emitting element is disposed on the substrate and is configured to provide a third color light with a third light-emitting center. The third light shield surrounds the third light-emitting element, and the third light shield has a third opening, wherein a width of the third opening is smaller than a length of the third opening. The first color light, the second color light, and the third color light have different wavelengths, and the first light-emitting center, the second light-emitting center, and the third light-emitting center define a triangle.

In one embodiment, the first color light, the second color light, and the third color light are a red light, a green light, and a blue light, respectively.

In one embodiment, the triangle defines a visual plane, the visual plane having an X-axis direction, a Y-axis direction, and a Z-axis direction that are mutually perpendicular, with the Z-axis direction being perpendicular to and passing through the visual plane.

In one embodiment, each of the openings defines a shape in a plane parallel to the visual plane, the shape has a median point, and a line connecting each of the median points and the light-emitting center is parallel to the Y-axis direction correspondingly, with each of the median points positioned below the light-emitting center correspondingly.

In one embodiment, each of the openings defines a shape in a plane parallel to the visual plane, with the width gradually narrowing downward.

In one embodiment, each of the openings has a tapering angle between 40 degrees and 70 degrees.

In one embodiment, each of the light-emitting elements has a downward viewing angle with respect to a direction parallel to the Y-axis direction, with the downward viewing angle being greater than 40 degrees and less than 90 degrees.

In one embodiment, with respect to a direction parallel to the Z-axis, a height of each of the light shields is greater than a height of each of the light-emitting elements, thereby shielding the first light-emitting center, the second light-emitting center, and the third light-emitting center, respectively.

In one embodiment, each of the light shields has the height of at least 3 millimeters (mm) above each of the light-emitting centers in the Z-axis direction.

In one embodiment, each of the light-emitting elements has a horizontal viewing angle with respect to a direction parallel to the X-axis direction, with the horizontal viewing angle being between 25 degrees and 90 degrees.

In one embodiment, a light-blocking plate is further positioned between the adjacent light-emitting units along the Y-axis direction, with each of the light-blocking plates having a height greater than the height of each of the light shields.

In one embodiment, each of the light-emitting elements has an installation axis that forms an angle greater than 0 degrees with a normal of the substrate.

In one embodiment, each of the light-emitting elements has an installation axis that forms an angle greater than 0 degrees but less than 12 degrees with a normal of the substrate.

In one embodiment, each of the light-emitting elements has an installation axis that forms an angle greater than 0 degrees, with the angle being 6 degrees.

In one embodiment, each of the light shields is adjacently positioned.

In one embodiment, the width of each of the openings is between 4 to 6 millimeters (mm), and the length of each of the openings is between 4 to 7 millimeters (mm).

In one embodiment, the width of each of the openings is 5 millimeters (mm), and the length of each of the openings is 6 millimeters (mm).

In one embodiment, a left side of the triangle is parallel to the Y-axis direction of the visual plane.

In one embodiment, the first light-emitting element is located at the lower endpoint of the left side, the second light-emitting element is located at the upper endpoint of the left side, and the third light-emitting element is located on a right side of the triangle.

In one embodiment, each of the light-emitting elements is a Light Emitting Diode (LED).

After referring to the drawings and the embodiments as described in the following, those the ordinary skilled in this art can understand other objectives of the present invention, as well as the technical means and embodiments of the present invention.

### BRIEF DESCRIPTION OF THE DRAWINGS

FIG. 1A is a partial perspective schematic view of a display device according to an embodiment of the present invention;

FIG. 1B is a partial exploded perspective view of the display device according to an embodiment of the present invention;

FIG. 2 is a partially enlarged schematic view of the display device according to an embodiment of the present invention;

FIG. 3 is a schematic view of a light-emitting unit according to an embodiment of the present invention;

FIG. 4 is a partial cross-sectional view of the display device along sectional line A-A′ in FIG. 2 according to an embodiment of the present invention; and

FIG. 5 is a partial cross-sectional view of the display device along sectional line B-B′ in FIG. 2 according to an embodiment of the present invention.

### DETAILED DESCRIPTION OF THE PREFERRED EMBODIMENT

In the following description, the present invention will be explained with reference to various embodiments thereof. These embodiments of the present invention are not intended to limit the present invention to any specific environment, application or particular method for implementations described in these embodiments. Therefore, the description of these embodiments is for illustrative purposes only and is not intended to limit the present invention.

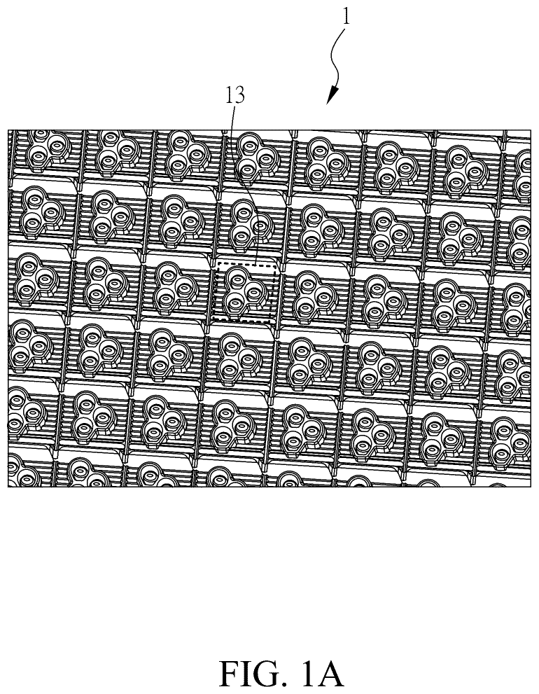

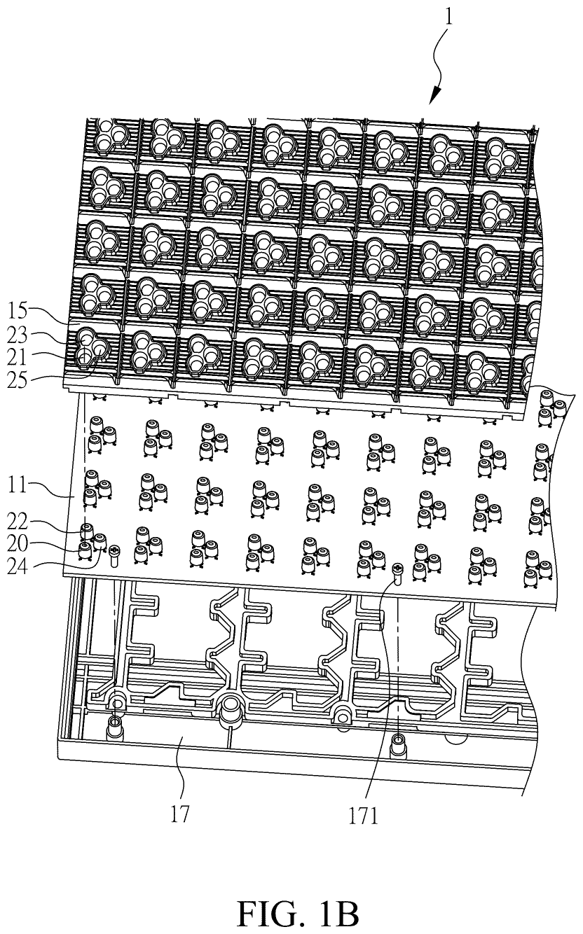

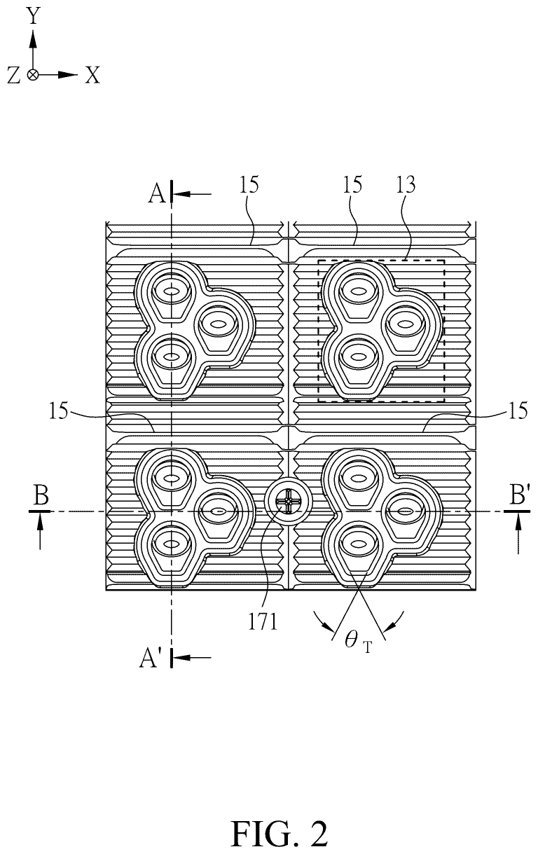

The display device 1 of the first embodiment of the present invention is shown in FIGS. 1A to 5. As illustrated in the partial perspective views of the display device 1 in FIGS. 1A and 1B and the partially enlarged schematic view of the display device 1 in FIG. 2, the display device 1 includes a substrate 11, a plurality of light-emitting units 13, a plurality of light-blocking plates 15, and a housing 17. The substrate 11 is mounted on the housing 17, and the light-emitting units 13 are disposed on the substrate 11, electrically connected to a driving circuit (not shown) and a power supply (not shown). The light-blocking plates 15 are arranged at intervals on the upper surface of the light-emitting units 13. The substrate 11 and the housing 17 are secured by a plurality of fastening elements 171 of the housing 17. In this embodiment, the fastening elements 171 are screws. However, in other implementation variations, they may also be rivets or other types of fastening elements.

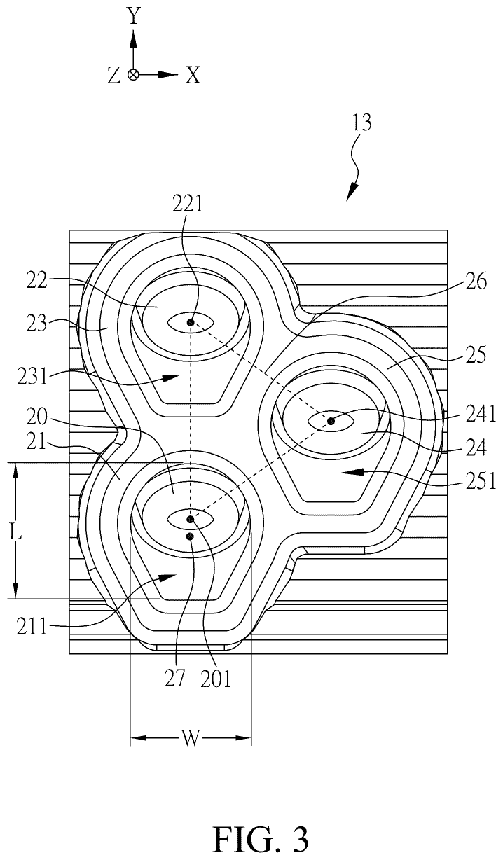

Referring simultaneously to FIGS. 2 through 5, each of the light-emitting units 13 includes a first light-emitting element 20, a first light shield 21, a second light-emitting element 22, a second light shield 23, a third light-emitting element 24, and a third light shield 25. More specifically, the first light-emitting element 20 is disposed on the substrate 11, configured to emit red light, and has a first light-emitting center 201. The first light shield 21 surrounds the first light-emitting element 20 and has a first opening 211. The width W of the first opening 211 is smaller than the length L of the first opening 211. The second light-emitting element 22 is disposed on the substrate 11, configured to emit green light, and has a second light-emitting center 221. The second light shield 23 surrounds the second light-emitting element 22 and has a second opening 231. The width of the second opening 231 is smaller than the length of the second opening 231. The third light-emitting element 24 is disposed on the substrate 11, configured to emit blue light, and has a third light-emitting center 241. The third light shield 25 surrounds the third light-emitting element 24 and has a third opening 251. The width of the third opening 251 is smaller than the length of the third opening 251. The emitted lights have different wavelengths, and the connection lines between the light-emitting centers form a triangle 26. It should be noted that for simplicity, in FIG. 3, only the width W and the length L of the first opening 211 of the first light shield 21 are indicated as an illustration. The aforementioned width W and length L refer to the distance at the widest and longest positions of the opening, respectively.

In this embodiment, the first color light, the second color light, and the third color light are red light, green light, and blue light, respectively. However, in other embodiments of the present invention, the correspondence between the first color light, the second color light, and the third color light and red, green, and blue lights can be altered into other sequences. Furthermore, the first color light, the second color light, and the third color light may also be selected from other wavelengths of light and are not limited to red, green, and blue. Additionally, in this embodiment, the first light-emitting element 20, the second light-emitting element 22, and the third light-emitting element 24 are all light-emitting diodes (LEDs). However, in other embodiments of the present invention, other types of light-emitting elements may also be used.

As described above, the connection of the first light-emitting center 201, the second light-emitting center 221, and the third light-emitting center 241 forms a triangle 26, which defines a visual plane. In other words, when the display device 1 is installed and operating, the front projection plane of the image displayed by the display device 1 is the visual plane. The visual plane includes an X-axis direction, a Y-axis direction, and a Z-axis direction, which are mutually perpendicular. The Z-axis direction is perpendicular to and passes through the visual plane. For ease of understanding, the X-axis, Y-axis, and Z-axis directions are indicated in FIGS. 2 through 5.

As shown in FIGS. 1A through 3, the first light-emitting element 20, the second light-emitting element 22, and the third light-emitting element 24 are eccentrically positioned upward along the Y-axis direction within the first opening 211, the second opening 231, and the third opening 251, respectively. To simplify the illustration and explanation, the following description will use the first light-emitting element 20, the first light shield 21, and the first opening 211 as examples. The aforementioned upward eccentricity refers to the center positions of the first light-emitting element 20, the second light-emitting element 22, and the third light-emitting element 24 being higher along the Y-axis direction than the center positions of the first opening 211, the second opening 231, and the third opening 251, respectively. Referring to FIG. 3, the first opening 211 has a shape in a plane parallel to the visual plane, and the shape has a median point 27. The line (not shown) connecting the median point 27 and the first light-emitting center 201 is parallel to the Y-axis direction, and the median point 27 is located below the first light-emitting center 201. Similarly, the second opening 231 and the third opening 251 have shapes in planes parallel to the visual plane, and the shapes have median points (not shown). The lines connecting the median points of the second opening 231 and the third opening 251 with their corresponding second light-emitting center 221 or third light-emitting center 241 are parallel to the Y-axis direction. Additionally, the median points of the second opening 231 and the third opening 251 are located below their respective second light-emitting center 221 or third light-emitting center 241.

The light-blocking plates 15, the first light shield 21, the second light shield 23, and the third light shield 25 are configured to reflect and guide light to project in the appropriate direction. In this embodiment, the shapes and dimensions of the first light shield 21, the second light shield 23, and the third light shield 25 are identical, and the corresponding openings 211, 231, and 251 of the three light shields also share the same width and length. Preferably, the width W of each opening 211, 231, and 251 is between 4 and 6 millimeters (mm), and the length L of each opening 211, 231, and 251 is between 4 and 7 millimeters (mm). More preferably, the width W of each opening 211, 231, and 251 is 5 millimeters (mm), and the length L is 6 millimeters (mm). It should be noted, however, that in other implementations of the present invention, the first light shield, the second light shield, and the third light shield may adopt different shapes.

The first opening 211 of the first light shield 21, the second opening 231 of the second light shield 23, and the third opening 251 of the third light shield 25 have shapes that taper in width downward in a plane parallel to the visual plane, thereby focusing the light toward the viewer's perspective. As shown in FIGS. 1A through 3, in this embodiment, the first opening 211, the second opening 231, and the third opening 251 resemble an inverted teardrop shape in their front view on a plane parallel to the visual plane. The tapering angle θ_{T} of each opening is between 40 degrees and 70 degrees. In other implementations of the present invention, the first light shield, the second light shield, and the third light shield may also adopt alternative opening shapes with downward tapering widths on a plane parallel to the visual plane, such as inverted triangles, balloon-like shapes, or other similar designs.

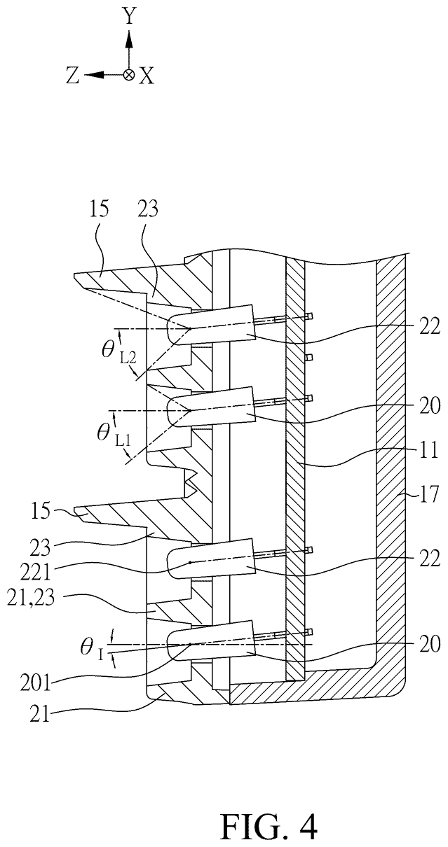

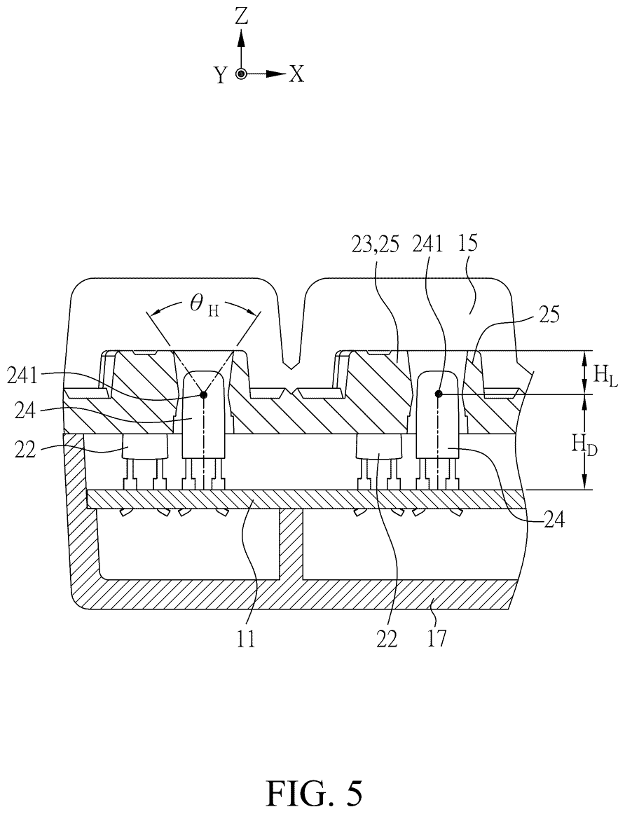

As shown in FIGS. 1A through 5, in this embodiment, the first light shield 21, the second light shield 23, and the third light shield 25 are arranged adjacent to each other and are integrally connected. Therefore, as seen in the cross-sectional view of FIG. 4, the adjacent portions of the first light shield 21 and the second light shield 23 along the Y-axis direction are connected into a single structure. Similarly, in the cross-sectional view of FIG. 5, the adjacent portions of the second light shield 23 and the third light shield 25 along the X-axis direction are also connected into a single structure. As illustrated in FIG. 1B, the first light shield 21, the second light shield 23, and the third light shield 25 are integrated into a single component, thereby reducing manufacturing steps, storage, and assembly costs. In other implementations of the present invention, the first light shield, the second light shield, and the third light shield may be arranged adjacent to one another but remain independent without being integrally connected.

In the display device 1 of the present invention, the light-blocking plates 15 are provided between adjacent light-emitting units 13 along the Y-axis direction. As shown in FIGS. 4 and 5, when viewed along the Z-axis direction, the height of each of the light-blocking plates 15 is greater than the height of the respective light shields 21, 23, and 25. As illustrated in the schematic view of FIG. 2 and the cross-sectional view of FIG. 4, in this embodiment, the light-blocking plates 15 are spaced apart from the first light shield 21 and the third light shield 25 while being closely connected to and integrated with the second light shield 23. In other words, through the adjacent second light shield 23, the light-blocking plates 15 are integrated with the first light shield 21, the second light shield 23, and the third light shield 25 into a single component, thereby achieving the aforementioned benefits of reduced manufacturing steps and costs. It should be noted that, in other embodiments, the light-blocking plates 15 may also be separate from the first light shield 21, the second light shield 23, and the third light shield 25, functioning as an independent part. In this embodiment, the light-blocking plates 15, the first light shield 21, the second light shield 23, and the third light shield 25 are made of the same material. However, in other embodiments, the light-blocking plates, the first light shield, the second light shield, and the third light shield may be manufactured from different materials.

Since display devices are usually large in area and installed at a certain height above the ground, viewers generally observe them from an upward angle. To reduce unnecessary light projection, the present invention adjusts the arrangement of the first light-emitting element 20, the second light-emitting element 22, the third light-emitting element 24, the first light shield 21, the second light shield 23, the third light shield 25, and the light-blocking plates 15. Specifically, the first light-emitting element 20, the second light-emitting element 22, and the third light-emitting element 24 have a downward viewing angle with respect to a direction parallel to the Y-axis direction. This downward viewing angle is greater than 40 degrees but less than 90 degrees. Referring to FIG. 4, in this embodiment, due to the block of the light-blocking plates 15, the downward viewing angle θ_{L1} of the first light-emitting element 20 is smaller than the downward viewing angle θ_{L2} of the second light-emitting element 22, such as 40 degrees and 44 degrees, respectively. Furthermore, to effectively utilize the light provided by the first light-emitting element 20, the second light-emitting element 22, and the third light-emitting element 24, the installation axis of these light-emitting elements forms an angle θ_{I} greater than 0 degrees with the normal of the substrate 11. With respect to the visual plane, the first light-emitting element 20, the second light-emitting element 22, and the third light-emitting element 24 are slightly tilted downward. Preferably, this downward angle θ_{I} is less than 12 degrees, and more preferably, it is 6 degrees.

As shown in FIGS. 4 and 5, along the Z-axis direction, the height of each of the first light shield 21, the second light shield 23, and the third light shield 25 is greater than the height of the respective first light-emitting element 20, the second light-emitting element 22, and the third light-emitting element 24. This configuration effectively blocks the first light-emitting center 201, the second light-emitting center 221, and the third light-emitting center 241 of the respective first light-emitting element 20, the second light-emitting element 22, and the third light-emitting element 24. Each of the first light shield 21, the second light shield 23, and the third light shield 25 extends above the height H_{L} of the corresponding light-emitting centers 201, 221, and 241 by at least 3 millimeters (mm) along the Z-axis direction. In this embodiment, the substrate 11 and each of the first light shield 21, the second light shield 23, and the third light shield 25 are mounted on the housing 17. Along the Z-axis direction, the first light shield 21, the second light shield 23, and the third light shield 25 are positioned higher than the substrate 11, thereby shielding the upper portions of the first light-emitting element 20, the second light-emitting element 22, and the third light-emitting element 24. The first light-emitting center 201, the second light-emitting center 221, and the third light-emitting center 241 of the respective first light-emitting element 20, the second light-emitting element 22, and the third light-emitting element 24 are spaced at a height H_{D} of approximately 7 to 9 millimeters (mm) from the upper surface of the substrate 11.

As shown in FIG. 5, the first light-emitting element 20, the second light-emitting element 22, and the third light-emitting element 24 are shielded by the respective first light shield 21, the second light shield 23, and the third light shield 25 along the X-axis direction. The first light-emitting element 20, the second light-emitting element 22, and the third light-emitting element 24 have a horizontal viewing angle θ_{H} with respect to a direction parallel to the X-axis direction. The optimal range for this horizontal viewing angle θ_{H} is between 25 degrees and 90 degrees, which helps reduce the impact of unnecessary light on the surrounding environment by defining the light range within the horizontal viewing angle.

In this embodiment of the present invention, the relative positions of the light-emitting centers 201, 221, and 241 on the visual plane form a triangle 26. As shown in FIG. 3, the left side of the triangle 26 is parallel to the Y-axis direction of the visual plane. The first light-emitting element 20 is located at a lower endpoint of the left side, the second light-emitting element 22 is located at an upper endpoint of the left side, and the third light-emitting element 24 is located on the right side of the triangle 26. In other embodiments of the present invention, the relative arrangement of the first, second, and third light-emitting elements may be slightly adjusted, causing the triangle 26 formed by the light-emitting centers 201, 221, and 241 to rotate on the visual plane.

The display device of the present invention utilizes individual light shields surrounding each light-emitting element to adjust the light projection angle. Specifically, the light-emitting elements are eccentrically positioned upward in light shields that have a width smaller than their length, providing narrower horizontal viewing angles. This configuration effectively blocks and reflects unnecessary light outside the viewing angle, concentrating the light within a specific visual range. This design enables the presentation of highly directional images while minimizing unnecessary light scattering to the surrounding environment, thereby reducing its impact on residents and drivers. This approach not only ensures the visibility and appeal of advertisements but also significantly reduces light pollution, enhancing the comfort and safety of the surrounding environment.

The above embodiments are used only to illustrate the implementations of the present invention and to explain the technical features of the present invention, and are not used to limit the scope of the present invention. Any modifications or equivalent arrangements that can be easily accomplished by people skilled in the art are considered to fall within the scope of the present invention, and the scope of the present invention should be limited by the claims of the patent application.

What is claimed is:

1. A display device comprising:
a substrate;
a plurality of light-emitting units, each of the light-emitting units having:
a first light-emitting element disposed on the substrate, wherein the first light-emitting element is configured to provide a first color light and has a first light-emitting center;
a first light shield surrounding the first light-emitting element, wherein the first light shield has a first opening, and a width of the first opening is smaller than a length of the first opening;
a second light-emitting element disposed on the substrate, wherein the second light-emitting element is configured to provide a second color light and has a second light-emitting center;
a second light shield surrounding the second light-emitting element, wherein the second light shield has a second opening, and a width of the second opening is smaller than a length of the second opening;
a third light-emitting element disposed on the substrate, wherein the third light-emitting element is configured to provide a third color light and has a third light-emitting center; and
a third light shield surrounding the third light-emitting element, wherein the third light shield has a third opening, and a width of the third opening is smaller than a length of the third opening;
wherein the first color light, the second color light, and the third color light have different wavelengths, and the first light-emitting center, the second light-emitting center, and the third light-emitting center define a triangle.

2. The display device according to claim 1, wherein the first color light, the second color light, and the third color light are a red light, a green light, and a blue light, respectively.

3. The display device according to claim 2, wherein the triangle defines a visual plane, the visual plane having an X-axis direction, a Y-axis direction, and a Z-axis direction that are mutually perpendicular, with the Z-axis direction being perpendicular to and passing through the visual plane.

4. The display device according to claim 3, wherein each of the openings defines a shape in a plane parallel to the visual plane, the shape has a median point, and a line connecting each of the median points and the light-emitting center is parallel to the Y-axis direction correspondingly, with each of the median points positioned below the light-emitting center correspondingly.

5. The display device according to claim 3, wherein each of the openings defines a shape in a plane parallel to the visual plane, with a width gradually narrowing downward.

6. The display device according to claim 4, wherein each of the openings has a tapering angle between 40 degrees and 70 degrees.

7. The display device according to claim 6, wherein each of the light-emitting elements has a downward viewing angle with respect to a direction parallel to the Y-axis direction, with the downward viewing angle being greater than 40 degrees and less than 90 degrees.

8. The display device according to claim 3, wherein, with respect to a direction parallel to the Z-axis direction, a height of each of the light shields is greater than a height of each of the light-emitting elements, thereby shielding the first light-emitting center, the second light-emitting center, and the third light-emitting center, respectively.

9. The display device according to claim 8, wherein each of the light shields has the height of at least 3 millimeters (mm) above each of the light-emitting centers in the Z-axis direction.

10. The display device according to claim 9, wherein each of the light-emitting elements has a horizontal viewing angle with respect to a direction parallel to the X-axis direction, with the horizontal viewing angle being between 25 degrees and 90 degrees.

11. The display device according to claim 3, further comprising a light-blocking plate positioned between the adjacent light-emitting units along the Y-axis direction, each of the light-blocking plates having a height greater than the height of each of the light shields.

12. The display device according to claim 1, wherein each of the light-emitting elements has an installation axis that forms an angle greater than 0 degrees with a normal of the substrate.

13. The display device according to claim 12, wherein the angle is less than 12 degrees.

14. The display device according to claim 13, wherein the angle is 6 degrees.

15. The display device according to claim 1, wherein each of the light shields is adjacently positioned.

16. The display device according to claim 1, wherein the width of each of the openings is between 4 to 6 millimeters (mm), and the length of each of the openings is between 4 to 7 millimeters (mm).

17. The display device according to claim 16, wherein the width of each of the openings is 5 millimeters (mm), and the length of each of the openings is 6 millimeters (mm).

18. The display device according to claim 3, wherein a left side of the triangle is parallel to the Y-axis direction of the visual plane.

19. The display device according to claim 18, wherein the first light-emitting element is located at a lower endpoint of the left side, the second light-emitting element is located at an upper endpoint of the left side, and the third light-emitting element is located on a right side of the triangle.

20. The display device according to claim 1, wherein each of the light-emitting elements is a Light Emitting Diode (LED).
